(19) United States
(12) Patent Application Publication
(10) Pub. No.: US 2015/0270160 A1
(43) Pub. Date: Sep. 24, 2015

(54) METHOD AND APPARATUS FOR FORMING SILICON OXIDE FILM

(71) Applicant: TOKYO ELECTRON LIMITED, Tokyo (JP)

(72) Inventor: Mitsuhiro OKADA, Nirasaki City (JP)

(21) Appl. No.: 14/657,573

(22) Filed: Mar. 13, 2015

(30) Foreign Application Priority Data
Mar. 19, 2014 (JP) 2014-056207

(51) Int. Cl. H01L 21/762; C23C 16/455; C23C 16/40; H01L 21/02; H01L 21/306

(52) U.S. Cl. CPC H01L 21/76232; H01L 21/02532; H01L 21/02164; H01L 21/02238; H01L 21/30604; H01L 21/02211; C23C 16/401; C23C 16/45544

(57) ABSTRACT

A method of forming a silicon oxide film for burying the silicon oxide film in a trench formed on a surface of a target object includes forming a silicon film on the trench of the target object, etching the silicon film, oxidizing the silicon film subjected to the etching to form a first silicon oxide film, and forming a second silicon oxide film on the first silicon oxide film to cover the first silicon oxide film formed through the oxidizing the silicon film while the second silicon oxide film is buried in the trench of the target object.

### CROSS-REFERENCE TO RELATED APPLICATION

This application claims the benefit of Japanese Patent Application No. 2014-056207, filed on Mar. 19, 2014, in the Japan Patent Office, the disclosure of which is incorporated herein in its entirety by reference.

### TECHNICAL FIELD

The present disclosure relates to a method and apparatus for forming a silicon oxide film.

### BACKGROUND

A process of manufacturing a semiconductor device or the like includes a process of forming a trench in a dielectric-conductor to bury a silicon oxide film in the trench. Regarding this process, a related art discloses a reaction between a silicon compound such as monosilane (SiH₄) and hydrogen peroxide by chemical vapor deposition (CVD).

On the other hand, miniaturization of a semiconductor device involves a need for increase in aspect ratio of the trench in which the silicon oxide film is buried. However, an increased aspect ratio involves a problem that voids or seams are easily generated when the silicon oxide film is buried. Therefore, a method of forming a silicon oxide film in which generation of voids or seams can be suppressed even in a high aspect ratio has been required.

### SUMMARY

Some embodiments of the present disclosure provide a method and apparatus for forming a silicon oxide film, which can suppress generation of voids or seams.

According to the present disclosure, provided is a method of forming a silicon oxide film for burying the silicon oxide film in a trench formed on a surface of a target object, the method including forming a silicon film on the trench of the target object; etching the silicon film; oxidizing the silicon film subjected to the etching to form a first silicon oxide film; and forming a second silicon oxide film on the first silicon oxide film to cover the first silicon oxide film formed through the oxidizing the silicon film while the second silicon oxide film is buried in the trench of the target object.

According to the present disclosure, provided is an apparatus for forming a silicon oxide film for burying the silicon oxide film in a trench formed on a surface of a target object accommodated in a reaction chamber, the apparatus including a silicon film forming gas supply unit configured to supply a gas for forming a silicon film into the reaction chamber; an etching gas supply unit configured to supply an etching gas for etching the silicon film into the reaction chamber; an oxidation gas supply unit configured to supply an oxidation gas for oxidizing the silicon film to form a first silicon oxide film into the reaction chamber; a silicon oxide film forming gas supply unit configured to supply a silicon oxide film forming gas into the reaction chamber; and a controller configured to control the silicon film forming gas supply unit, the etching gas supply unit, the oxidation gas supply unit and the silicon oxide film forming gas supply unit, wherein the controller controls the silicon film forming gas supply unit to form the silicon film on the trench of the target object, controls the etching gas supply unit to etch the silicon film, controls the oxidation gas supply unit to oxidize the etched silicon film to form the first silicon oxide film, and controls the silicon oxide film forming gas supply unit to form a second silicon oxide film covering the first silicon oxide film formed through oxidation of the silicon film while the second silicon oxide film is buried in the trench of the target object.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view showing a processing apparatus according to one embodiment of the present disclosure.

FIG. 2 is a view showing a configuration of a controller shown in FIG. 1.

FIG. 3 is a view showing a recipe for a method of forming a silicon oxide film according to one embodiment of the present disclosure.

FIGS. 4A to 4D show sectional views of surface shapes of semiconductor wafers.

FIG. 5 is a view for explaining a silicon film-forming process according to another embodiment of the present disclosure.

FIG. 6 is a view for explaining a silicon film-forming process according to another embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

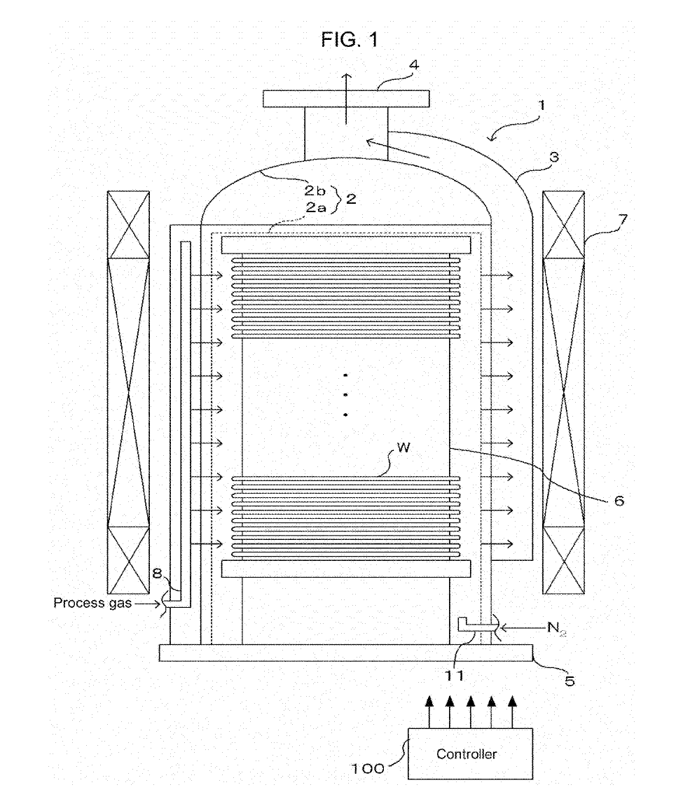

Hereinafter, a method and apparatus for forming a silicon oxide film according to the present disclosure will now be described in detail. In the present embodiment, a description will be given by way of an example in which a batch-type vertical processing apparatus as shown in FIG. 1 is used as an apparatus for forming a silicon oxide film.

Referring to FIG. 1, the processing apparatus 1 includes a reaction tube (reaction chamber) 2, a longitudinal direction of which extends in the vertical direction. The reaction tube 2 has a double tube structure including an inner tube 2a, and an outer tube 2b having a ceiling, wherein the outer tube 2b covers the inner tube 2a, being separated from the inner tube 2a by a predetermined distance. Sidewalls of the inner tube 2a and the outer tube 2b have a plurality of openings as indicated by arrows in FIG. 1. The inner tube 2a and the outer tube 2b are made of a material having excellent properties in terms of heat resistance and corrosion resistance, for example, quartz.

An exhaust unit 3 which exhausts gas from the reaction tube 2 is provided at one side of the reaction tube 2. The exhaust unit 3 extends upward along the reaction tube 2 and communicates with the reaction tube 2 through the openings formed in the sidewall of the reaction tube 2. The exhaust unit 3 is connected at an upper end thereof to an exhaust port 4 arranged at an upper portion of the reaction tube 2. The exhaust port 4 is connected to an exhaust pipe (not shown) to which a pressure regulating mechanism such as a valve (not shown) and a vacuum pump 127 described below is disposed. By virtue of the pressure regulating mechanism, a gas supplied from one side of the sidewall of the outer tube 2b (a process gas supply pipe 8) is exhausted to the exhaust pipe through the inner tube 2a, the other side sidewall of the outer tube 2b, the exhaust unit 3, and the exhaust port 4, whereby the interior of the reaction tube 2 is controlled to a desired pressure (a degree of vacuum).

A lid 5 is disposed under the reaction tube 2. The lid 5 is made of a material having excellent properties in terms of heat resistance and corrosion resistance, for example, quartz. The lid 5 can be moved up and down by a boat elevator 128 described below. When the lid 5 is moved up by the boat elevator 128, a lower end (furnace port) of the reaction tube 2 is closed, while the lid 5 is moved down by the boat elevator 128, the lower end (furnace port) of the reaction tube 2 is open.

A wafer boat 6 is mounted on the lid 5. The wafer boat 6 is made of, for example, quartz. The wafer boat 6 is configured to accommodate a plurality of semiconductor wafers W such that a plurality of semiconductor wafers W is separated a predetermined distance from each other in the vertical direction. Furthermore, a heat insulating container, which prevents reduction in internal temperature of the reaction tube 2 through the furnace port of the reaction tube 2, or a rotary table on which the wafer boat 6 for accommodating the semiconductor wafers W is rotatably mounted may be disposed on the lid 5. The wafer boat 6 may be mounted on the heat insulating container or the rotary table. In this case, it is easy to uniformly control the temperature of the semiconductor wafers W accommodated within the wafer boat 6.

Heaters 7 formed of, for example, a resistance heating element, are disposed around the reaction tube 2, surrounding the reaction tube 2. The interior of the reaction tube 2 is heated to a predetermined temperature by the heaters 7. As a result, the semiconductor wafers W accommodated within the reaction tube 2 are heated to a predetermined temperature.

The process gas supply pipe 8 for supplying a process gas into the reaction tube 2 (the outer tube 2b) extends through a side wall near the lower end of the reaction tube 2. Examples of the process gas may include disilane (Si₂H₆) and monosilane (SiH₄) as a gas for forming a silicon film, chlorine (Cl₂) and fluorine (F₂) as an etching gas, oxygen (0₂) and ozone (0₃) as an oxidation gas, TEOS (tetraethylorthosilicate) and barium titanate (BTO) as a gas for forming a silicon oxide film, and the like.

A plurality of supply holes is formed in the process gas supply pipe 8 with a predetermined interval between the supply holes in the vertical direction. The process gas is supplied into the reaction tube 2 (the outer tube 2b) through the supply holes. Thus, as indicated by arrows in FIG. 1, the process gas is supplied into the reaction tube 2 from a plurality of places arranged in the vertical direction.

A nitrogen gas supply pipe 11 for supplying nitrogen (N₂) as a dilution gas and a purge gas into the reaction tube 2 (the outer tube 2b) extends through the sidewall near the lower end of the reaction tube 2.

The process gas supply pipe 8 and the nitrogen gas supply pipe 11 are connected to gas supply sources (not shown) through mass flow controllers (MFCs) 125 described below.

A plurality of temperature sensors 122 formed of, for example, thermocouples, for measuring the internal temperature of the reaction tube 2 and a plurality of pressure gauges 123 for measuring the internal pressure of the reaction tube 2 are disposed within the reaction tube 2.

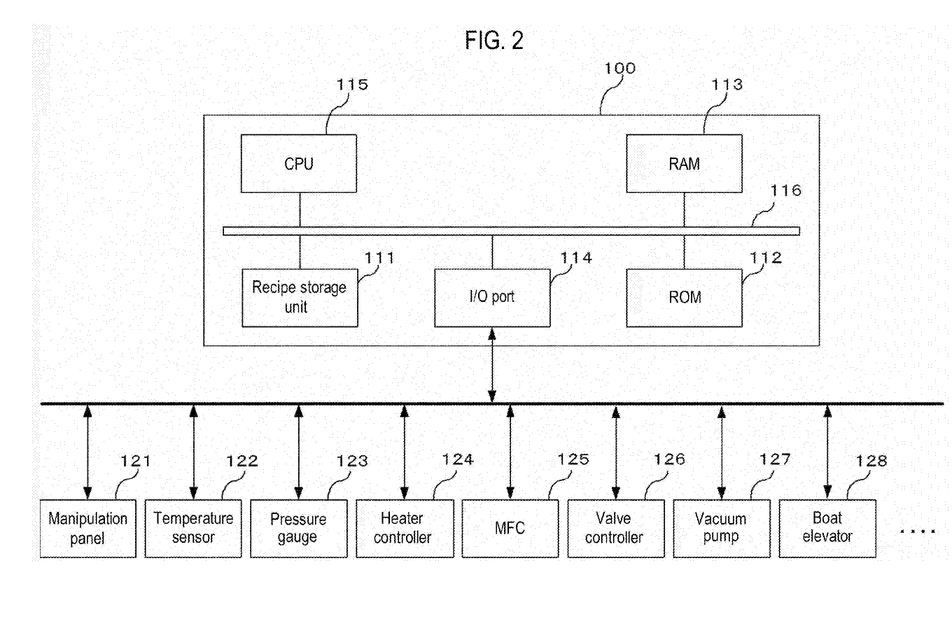

The processing apparatus 1 further includes a controller 100 configured to control the respective components of the apparatus. FIG. 2 shows the configuration of the controller 100. As shown in FIG. 2, a manipulation panel 121, the temperature sensors 122, the pressure gauges 123, a heater controller 124, the MFCs 125, valve controllers 126, the vacuum pump 127, the boat elevator 128 and the like are connected to the controller 100.

The manipulation panel 121 is provided with a display and manipulation buttons to transmit operator's instructions to the controller 100 and to display a variety of information received from the controller 100 on the display thereof.

The temperature sensors 122 measure the temperatures of the respective components within the reaction tube 2 and within the exhaust pipe, and inform the controller 100 of the measured values. The pressure gauges 123 measure the pressures of the respective components within the reaction tube 2 and within the exhaust pipe, and inform the controller 100 of the measured values.

The heater controller 124 individually controls the heaters 7. In response to instructions received from the controller 100, the heater controller 124 applies electric current to the heaters 7 to heat the heaters 7. Moreover, the heater controller 124 measures power consumption of the respective heaters 7 and informs the controller 100 of the measured values.

The respective MFCs 125 are disposed in the respective pipes such as the process gas supply pipe 8 and the nitrogen gas supply pipe 11, to control flow rates of gases flowing through the respective gas supply pipes at rates instructed by the controller 100. In addition, the MFCs 125 measure the actual flow rates of the gases to inform the controller 100 of the measured flow rates.

The valve controllers 126 are disposed in the respective pipes and control the opening degrees of the valves disposed in the respective pipes to the values instructed by the controller 100. The vacuum pump 127 is connected to the exhaust pipe and exhausts the gas from the reaction tube 2.

The boat elevator 128 moves the lid 5 upward to load the wafer boat 6 (the semiconductor wafers W) into the reaction tube 2, and moves the lid 5 downward to unload the wafer boat 6 (the semiconductor wafers W) from the interior of the reaction tube 2.

The controller 100 includes a recipe storage unit 111, a read only memory (ROM) 112, a random access memory (RAM) 113, an input/output (I/O) port 114, a central processing unit (CPU) 115, and a bus 116 interconnecting these components to one another.

A setup recipe and a plurality of process recipes are stored in the recipe storage unit 111. When the processing apparatus 1 is manufactured, only the setup recipe is stored in the recipe storage unit 111. The setup recipe is executed to individually generate thermal models and the like for respective processing apparatuses. The process recipe is prepared for each process actually performed by a user. Each of the process recipes defines temperature changes of the respective components, pressure changes within the reaction tube 2, and supply start/stop timings and supply amounts of various types of gases, during the time period from when the semiconductor wafers W are loaded into the reaction tube 2 to when the processed semiconductor wafers W are unloaded from the reaction tube 2.

The ROM 112 is implemented by an electrically erasable programmable read only memory (EEPROM), a flash memory, a hard disk or the like. The ROM 112 is a recording medium that stores an operation program of the CPU 115. The RAM 113 serves as a work area or the like of the CPU 115.

The I/O port 114 is connected to the manipulation panel 121, the temperature sensors 122, the pressure gauges 123, the heater controller 124, the MFCs 125, the valve controllers 126, the vacuum pump 127, the boat elevator 128, and the like, to control the input and output of data or signals.

The CPU 115 constitutes a core of the controller 100 and executes the control program stored in the ROM 112. In response to instructions received through the manipulation panel 121, the CPU 115 controls operation of the processing apparatus 1 according to the recipes (process recipes) stored in the recipe storage unit 111. That is, the CPU 115 allows the temperature sensors 122, the pressure gauges 123 and the MFCs 125 to measure the temperatures, pressures, and flow rates of the respective components within the reaction tube 2 and within the exhaust pipe. Based on the measurement data, the CPU 115 outputs control signals to the heater controller 124, the MFCs 125, the valve controllers 126, the vacuum pump 127 and the like, thereby controlling the respective components in accordance with the process recipes. The bus 116 delivers information between the respective components.

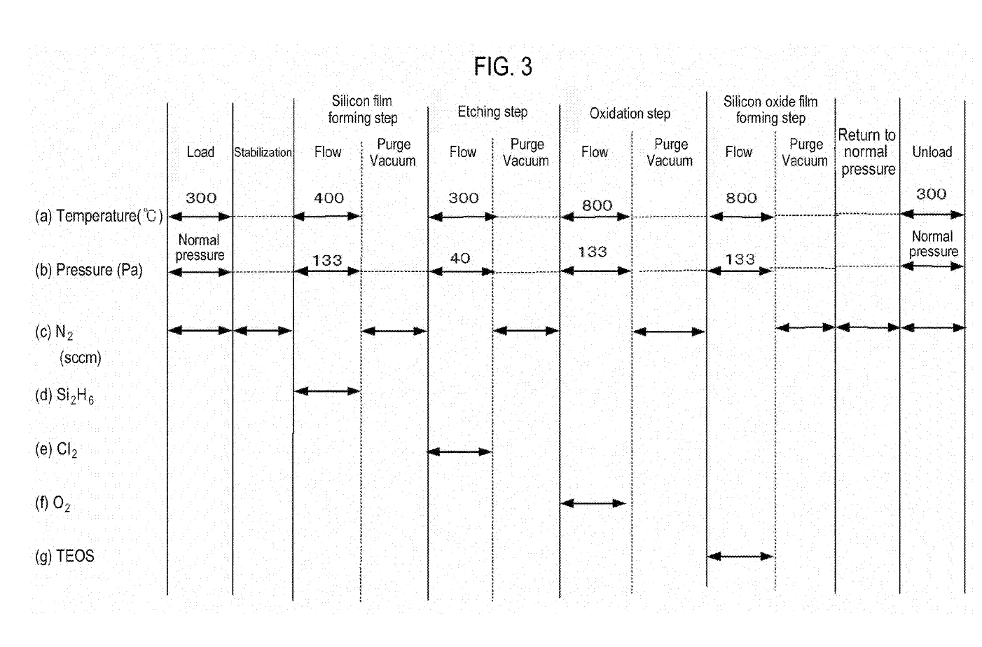

Next, a method of forming a silicon oxide film using the processing apparatus 1 configured as above will be described. In the following description, operations of the respective components constituting the processing apparatus 1 are controlled by the controller 100 (the CPU 115). In addition, the controller 100 (the CPU 115) controls the heater controller 124 (the heaters 7 for raising temperature), the MFCs 125, the valve controllers 126, and the like in the aforementioned manner, such that the temperature, pressure and flow rates of gases in the reaction tube 2 in the respective processes are set to conditions conforming to the recipe (time sequence) as shown in FIG. 3.

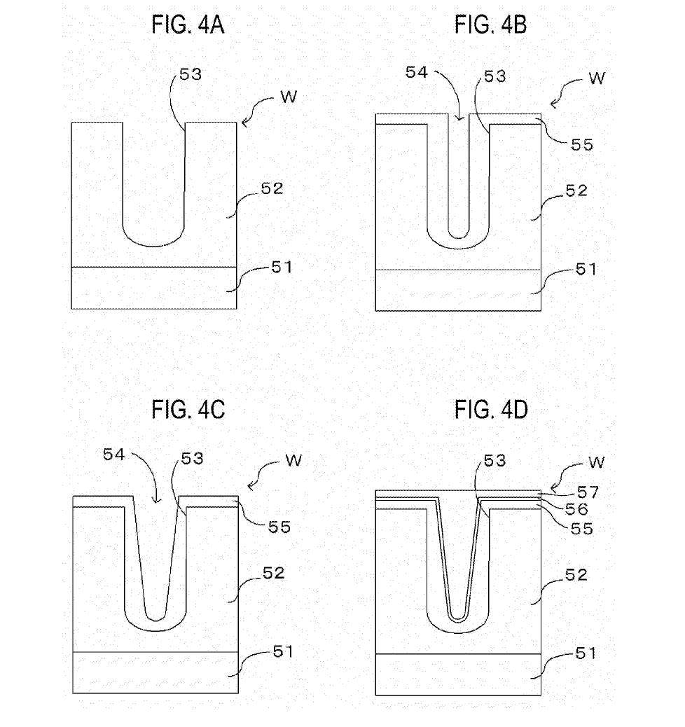

Further, in this embodiment, as shown in FIGS. 4A to 4D, a semiconductor wafer W which is a target object to be processed has a trench 53 formed in a first silicon film 52 as a conductor on a substrate 51, and a silicon oxide film is formed to be buried in the trench 53.

First, an inner temperature of the reaction tube 2 is set to a certain temperature, for example, 300 degrees C., as shown in (a) of FIG. 3. Further, a certain amount of nitrogen is supplied from the nitrogen gas supply pipe 11 into the reaction tube 2, as shown in (c) of FIG. 3. Then, the wafer boat 6 in which the semiconductor wafer W as shown in FIG. 4A is accommodated is loaded on the lid 5. Then, the lid 5 is moved up by the boat elevator 128 to load the semiconductor wafer W (wafer boat 6) into the reaction tube 2 (loading process).

Next, the interior of the reaction tube 2 is set to a certain temperature, for example, 400 degrees C., as shown in (a) of FIG. 3, while a certain amount of nitrogen is supplied from the nitrogen gas supply pipe 11 into the reaction tube 2, as shown in (c) of FIG. 3. Further, the reaction tube 2 is depressurized to a certain pressure, for example, 133 Pa (1 Torr), as shown in (d) of FIG. 3. Then, the interior of the reaction tube 2 is stabilized at this temperature and pressure (stabilization process).

The inner temperature of the reaction tube 2 may range from 200 degrees C. to 600 degrees C., and in some embodiments, 350 degrees C. to 550 degrees C. By setting the inner temperature of the reaction tube 2 in this range, it is possible to enhance film quality and thickness uniformity of a silicon film formed on the wafer.

The inner pressure of the reaction tube 2 may range from 0.133 Pa (0.001 Torr) to 13.3 kPa (100 Torr). Within this range of the inner pressure of the reaction tube, it is possible to promote reaction between the semiconductor wafer W and Si. The inner pressure of the reaction tube 2 may range from 13.3 Pa (0.1 Torr) to 1330 Pa (10 Torr) in some embodiments. Within this range of the inner pressure of the reaction tube, it is possible to facilitate pressure adjustment in the reaction tube 2.

When the reaction tube 2 is stabilized at a certain pressure and temperature, supply of nitrogen from the nitrogen gas supply pipe 11 is stopped and a film forming gas is supplied into the reaction tube 2. Specifically, a certain amount of disilane (Si₂H₆) is supplied from the process gas supply pipe 8 (flow process), as shown in (d) of FIG. 3.

Disilane supplied into the reaction tube 2 is heated and activated within the reaction tube 2. Accordingly, when disilane is supplied into the reaction tube 2, the semiconductor wafer W reacts with activated Si such that a certain amount of Si is adsorbed onto the semiconductor wafer W. As a result, a second silicon film 55 having a trench portion 54 is formed on the semiconductor wafer W, as shown in FIG. 4B.

When a certain amount of Si is adsorbed onto the semiconductor wafer W, supply of disilane from the process gas supply pipe 8 is stopped. Then, a certain amount of nitrogen is supplied from the nitrogen gas supply pipe 11 into the reaction tube 2 as shown in (c) of FIG. 3 while exhausting the gas from the reaction tube 2, so that the gas in the reaction tube 2 is exhausted outside (purge/vacuum process).

Further, the inner temperature of the reaction tube 2 is set to a certain temperature, for example, 300 degrees C., as shown in (a) of FIG. 3, while a certain amount of nitrogen is supplied from the nitrogen gas supply pipe 11 into the reaction tube 2, as shown in (c) of FIG. 3. Further, the gas is exhausted from the reaction tube 2 and the reaction tube 2 is depressurized to a certain pressure, for example, 40 Pa (0.3 Torr), as shown in (b) of FIG. 3.

Here, the inner temperature of the reaction tube 2 may range from 200 degrees C. to 350 degrees C., and in some embodiments, 250 degrees C. to 325 degrees C. The inner pressure of the reaction tube 2 may range from 1.33 Pa (0.01 Torr) to 1330 Pa (10 Torr), and in some embodiments, 13.3 Pa (0.1 Torr) to 133 kPa (1 Torr). These ranges of the inner temperature and pressure of the reaction tube 2 can secure efficient etching.

Then, supply of nitrogen from the nitrogen gas supply pipe 11 is stopped and an etching gas is supplied into the reaction tube 2. Specifically, a certain amount of chlorine (Cl₂) is supplied from the process gas supply pipe 8 (flow process), as shown in (e) of FIG. 3.

In the reaction tube 2, chlorine supplied into the reaction tube 2 is heated and activated to etch the second silicon film 55 in the trench 53 of the semiconductor wafer W. As a result, a V-shaped trench portion 54 is formed on the second silicon film 55 of the semiconductor wafer W, as shown in FIG. 4C.

After the V-shaped trench portion 54 is formed on the second silicon film 55 of the semiconductor wafer W, supply of chlorine from the process gas supply pipe 8 is stopped. Then, a certain amount of nitrogen is supplied from the nitrogen gas supply pipe 11 into the reaction tube 2 as shown in (c) of FIG. 3 while exhausting the gas from the reaction tube 2, whereby the gas in the reaction tube 2 is exhausted (purge/vacuum process).

Further, the inner temperature of the reaction tube 2 is set to a certain temperature, for example, 800 degrees C., as shown in (a) of FIG. 3, while a certain amount of nitrogen is supplied from the nitrogen gas supply pipe 11 into the reaction tube 2, as shown in (c) of FIG. 3. Further, the gas is exhausted from the reaction tube 2 and the reaction tube 2 is pressurized to a certain pressure, for example, 133 Pa (1 Torr), as shown in (b) of FIG. 3.

Here, the inner temperature of the reaction tube 2 may range from 450 degrees C. to 1000 degrees C., and in some embodiments, 700 degrees C. to 900 degrees C. The inner pressure of the reaction tube 2 may range from 0.133 Pa (0.001 Torr) to 13.3 kPa (100 Torr), and in some embodiments, 13.3 Pa (0.1 Torr) to 1330 Pa (10 Torr). These ranges of the inner temperature and pressure of the reaction tube 2 can secure efficient oxidation of the silicon film formed on the semiconductor wafer.

Then, supply of nitrogen from the nitrogen gas supply pipe 11 is stopped and an oxidation gas is supplied into the reaction tube 2. Specifically, a certain amount of oxygen (O₂) is supplied from the process gas supply pipe 8 (flow process), as shown in (f) of FIG. 3.

In the reaction tube 2, oxygen supplied into the reaction tube 2 is heated and activated to form an oxygen radical. The second silicon film 55 is oxidized by the oxygen radical to form a first silicon oxide film 56 as shown in FIG. 4D.

After the second silicon film 55 is oxidized to form the first silicon oxide film 56, supply of oxygen from the process gas supply pipe 8 is stopped. Then, a certain amount of nitrogen is supplied from the nitrogen gas supply pipe 11 into the reaction tube 2 while exhausting the gas from the reaction tube 2, as shown in (c) of FIG. 3, whereby the gas in the reaction tube 2 is exhausted (purge/vacuum process).

Further, the inner temperature of the reaction tube 2 is set to a certain temperature, for example, 800 degrees C., as shown in (a) of FIG. 3, while a certain amount of nitrogen is supplied from the nitrogen gas supply pipe 11 into the reaction tube 2, as shown in (c) of FIG. 3. Further, the reaction tube 2 is pressurized to a certain pressure, for example, 133 Pa (1 Torr), as shown in (b) of FIG. 3.

Then, supply of nitrogen from the nitrogen gas supply pipe 11 is stopped and a gas for forming a silicon oxide film is supplied into the reaction tube 2. Specifically, a certain amount of TEOS (Tetraethyl orthosilicate) is supplied from the process gas supply pipe 8 (flow process), as shown in (g) of FIG. 3.

In the reaction tube 2, TEOS supplied into the reaction tube 2 is heated and activated to form a second silicon oxide film 57 on the first silicon oxide film 56, as shown in FIG. 4D.

Here, as shown in FIG. 4D, due to the V-shaped trench portion 54 formed on the first silicon oxide film 56, which is formed by etching and oxidizing the second silicon film 55, voids or seams are difficult to occur when the second silicon oxide film 57 is buried in the V-shaped trench portion 54 during forming the second silicon oxide film 57 on the first silicon oxide film 56. Accordingly, it is possible to suppress generation of voids or seams, for example, even when the aspect ratio is increased.

After a desired silicon oxide film is formed on the semiconductor wafer W, the reaction tube 2 is maintained at a predetermined unload temperature, for example, at 300 degrees C. as shown in (a) of FIG. 3, by the heaters 7 while a certain amount of nitrogen is supplied from the nitrogen gas supply pipe 11 into the reaction tube 2 for a cycle-purge of the reaction tube 2 with nitrogen, so that the interior of the reaction tube 2 is returned to normal pressure (normal pressure returning process). Then, the lid 5 is moved down by the boat elevator 128 to unload the semiconductor wafer W (unloading process).

As described above, according to the embodiment of the present disclosure, the second silicon film 55 having the trench portion 54 is formed in the trench 53 of the first silicon film 52 and is subjected to etching such that the trench portion 54 has a V-shaped cross-section. Then, the second silicon film 55 is oxidized to form the first silicon oxide film 56 and the second silicon oxide film 57 is buried in the V-shaped trench portion 54. As a result, for example, even in a high aspect ratio, a silicon oxide film can be formed while generation of voids or seams is suppressed.

Furthermore, it should be understood that the present disclosure is not limited to the above embodiment and various modifications and alterations can be made. Hereinafter, other embodiments of the present disclosure will be described.

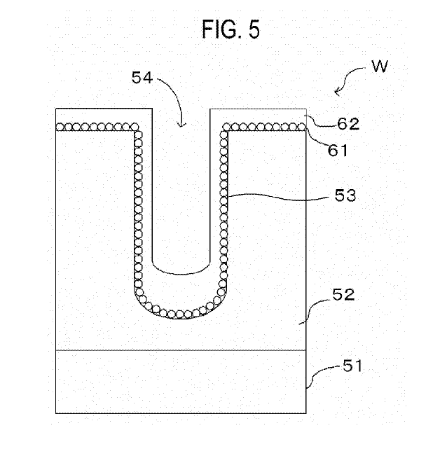

In the aforementioned embodiments, the present disclosure has been described by way of an example wherein the silicon film is formed using disilane. However, for example, an aminosilane layer 61 may be first formed by adsorption of an aminosilane gas as a seed layer and then a silicon film 62 is formed using disilane on the aminosilane layer 61, as shown in FIG. 5. In this case, the silicon film 62 may have improved quality (for example, in-plane uniformity). Examples of aminosilane used for forming the aminosilane layer 61 include butylaminosilane (BAS), bis(tert-butylamino)silane (BTBAS), dimethylaminosilane (DMAS), tris(dimethylamino)silane (TDMAS), diethylaminosilane (DEAS), bis(diethylamino)silane (BDEAS), dipropylaminosilane (DPAS), and diisopropylaminosilane (DIPAS).

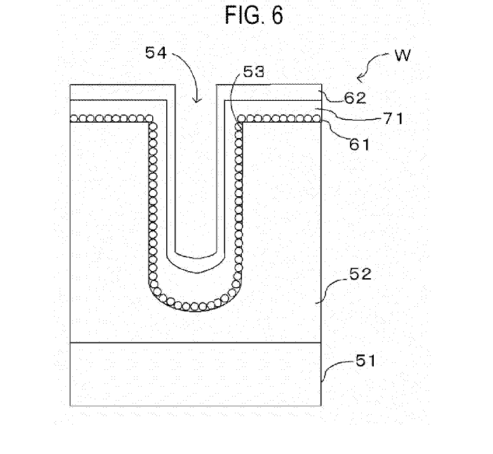

Further, a process of forming a silicon film 71 using disilane under a higher pressure than in the process of forming the silicon film 62 using disilane may be further performed between the process of adsorbing the aminosilane gas to form the aminosilane layer 61 as a seed layer and the process of forming the silicon film 62 using disilane, as shown in FIG. 6. In this case, an incubation time can be reduced, thereby preventing deterioration in surface roughness of the silicon film 62. As a result, it is possible to form a silicon film 62 having good surface roughness and coverage. In this way, when the silicon film having good surface roughness and coverage is formed, it is possible to improve surface roughness and coverage of a silicon oxide film formed on the silicon film.

In the aforementioned embodiments, the present disclosure has been described by way of an example wherein the first silicon oxide film 56 is formed on the first silicon film 52 having the trench 53. However, it should be understood that the present disclosure is not limited to the silicon film having the trench and may be applied to, for example, a SiC film, a SiO film and a SiN film.

In the aforementioned embodiments, the present disclosure has been described by way of an example wherein etching is performed such that the trench portion 54 has a V-shaped cross-section. However, it should be understood that the trench portion 54 may have any shape without being limited to the V-shaped cross-section so long as an upper portion of the trench portion 54 is open to allow the silicon oxide film to reach the bottom of the trench in the process of forming the silicon oxide film.

In the aforementioned embodiments, the present disclosure has been described by way of an example wherein chlorine is used as an etching gas. However, it should be understood that various etching gases such as fluorine (F₂) may be used so long as the etching gas can form a V-shape in the trench portion 54 of the silicon film.

In the aforementioned embodiments, the present disclosure has been described by way of an example wherein oxygen is used as an oxidation gas. However, various oxidation gases such as ozone (0₃) may be used so long as the oxidation gas can form the silicon oxide film 56 through oxidation of the second silicon film 55.

In the aforementioned embodiments, the present disclosure has been described by way of an example wherein the second silicon oxide film 57 is formed using TEOS as the film forming gas through CVD. However, various film forming gases may be used. Further, the silicon oxide film may be formed through atomic layer deposition (ALD).

In the aforementioned embodiments, the present disclosure has been described by way of an example wherein only the process gas is supplied during supply of the process gas. Alternatively, nitrogen may also be supplied as a diluting gas during supply of the process gas. When nitrogen is supplied as the diluting gas, it is easy to set the process time or the like. The diluting gas may be an inert gas and includes, in addition to nitrogen, for example, helium (He), neon (Ne), argon (Ar), krypton (Kr), or xenon (Xe).

In the aforementioned embodiments, the present disclosure has been described by way of an example wherein the batch-type processing apparatus having a double tube structure is used as the processing apparatus 1. However, for example, the present disclosure may be applied to a batch-type processing apparatus having a single tube structure. Moreover, the present disclosure may be applied to a batch-type horizontal processing apparatus or a single-substrate type processing apparatus.

The controller 100 employed in the embodiments of the present disclosure may be realized using a typical computer system instead of a dedicated computer system. For example, the controller 100 for performing the aforementioned processes may be configured by installing programs for executing processes onto a general-purpose computer from a recording medium (a flexible disk, a compact disc-read only memory (CD-ROM), or the like) which stores the programs for performing the aforementioned processes.

The programs may be provided by arbitrary means. The programs may be provided not only by the recording medium mentioned above but also through a communication line, a communication network, a communication system or the like. In this case, the programs may be posted on a bulletin board (BBS: Bulletin Board System) and provided through a network.

The program thus provided is executed in the same manner as other application programs under the control of an operating system (OS), thereby performing the processes described above.

According to the present disclosure, it is possible to suppress generation of voids or seams.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method of forming a silicon oxide film for burying the silicon oxide film in a trench formed on a surface of a target object, the method comprising:
forming a silicon film on the trench of the target object;
etching the silicon film;
oxidizing the silicon film subjected to the etching to form a first silicon oxide film; and
forming a second silicon oxide film on the first silicon oxide film to cover the first silicon oxide film formed through the oxidizing the silicon film while the second silicon oxide film is buried in the trench of the target object.

2. The method of claim 1, wherein, in the etching the silicon film, the etching is performed such that a V-shaped trench portion is formed.

3. The method of claim 1, wherein, in the forming a silicon film, the silicon film is formed after aminosilane is adsorbed onto the trench of the target object.

4. The method of claim 3, wherein the forming a silicon film includes:
a first process of forming the silicon film on the trench of the target object, to which aminosilane is adsorbed, under a first pressure; and
a second process of forming another silicon film on the silicon film under a second pressure lower than the first pressure.

5. An apparatus for forming a silicon oxide film for burying the silicon oxide film in a trench formed on a surface of a target object accommodated in a reaction chamber, the apparatus comprising:
a silicon film forming gas supply unit configured to supply a gas for forming a silicon film into the reaction chamber;
an etching gas supply unit configured to supply an etching gas for etching the silicon film into the reaction chamber;
an oxidation gas supply unit configured to supply an oxidation gas for oxidizing the silicon film to form a first silicon oxide film into the reaction chamber;
a silicon oxide film forming gas supply unit configured to supply a silicon oxide film forming gas into the reaction chamber; and
a controller configured to control the silicon film forming gas supply unit, the etching gas supply unit, the oxidation gas supply unit and the silicon oxide film forming gas supply unit,
wherein the controller controls the silicon film forming gas supply unit to form the silicon film on the trench of the target object, controls the etching gas supply unit to etch the silicon film, controls the oxidation gas supply unit to oxidize the etched silicon film to form the first silicon oxide film, and controls the silicon oxide film forming gas supply unit to form a second silicon oxide film covering the first silicon oxide film formed through oxidation of the silicon film while the second silicon oxide film is buried in the trench of the target object.

6. The apparatus of claim 5, wherein the controller controls the etching gas supply unit to etch the silicon film such that a V-shaped trench portion is formed in the silicon film.

7. The apparatus of claim 5, further comprising:
an aminosilane gas supply unit configured to supply an aminosilane gas into the reaction chamber,
wherein the controller controls the silicon film forming supply unit to form the silicon film on the trench of the target object after controlling the aminosilane gas supply unit to adsorb aminosilane onto the trench of the target object.

8. The apparatus of claim 7, further comprising:
a pressure setting unit configured to set an inner pressure of the reaction chamber,
wherein the controller controls the pressure setting unit to set the inner pressure of the reaction chamber to a first pressure and controls the silicon film forming gas supply unit to form the silicon film on the trench of the target object, to which aminosilane is adsorbed, under the first pressure, and, after that, controls the pressure setting unit to set the inner pressure of the reaction chamber to a second pressure lower than the first pressure and controls the silicon film forming gas supply unit to form another silicon film on the silicon film under the second pressure.
